(19) United States
(12) Patent Application Publication
(10) Pub. No.: US 2026/0059974 A1
(43) Pub. Date: Feb. 26, 2026

(54) DISPLAY DEVICE AND METHOD OF MANUFACTURING THE SAME

(71) Applicant: Samsung Display Co., Ltd., Yongin-Si, Gyeonggi-Do (KR)

(72) Inventor: Sungmin Huch, Yongin-si, Gyeonggi-do (KR)

(21) Appl. No.: 18/757,555

(22) Filed: Jun. 28, 2024

(30) Foreign Application Priority Data
Dec. 14, 2023 (KR) 10-2023-0182086

(51) Int. Cl. H10K 59/80; H10K 59/12; H10K 59/121

(52) U.S. Cl. CPC H10K 59/873; H10K 59/1201; H10K 59/1213

(57) ABSTRACT

A display device is disclosed that includes a substrate, a pixel circuit layer disposed on the substrate and including a thin-film transistor, a display element layer disposed on the pixel circuit layer and including a pixel electrode, a capping layer disposed on the display element layer and including an organic material, and an encapsulation layer disposed on the capping layer. The encapsulation layer includes a first inorganic encapsulation layer, an organic encapsulation layer disposed on the first inorganic encapsulation layer, and a second inorganic encapsulation layer disposed on the organic encapsulation layer. The capping layer includes a first capping layer portion, and a second capping layer portion disposed on the first capping layer portion and in contact with the first inorganic encapsulation layer, the second capping layer portion having a higher concentration of hydrogen than the first capping layer portion.

### CROSS-REFERENCE TO RELATED APPLICATION

This application is based on and claims priority under 35 U.S.C. § 119 to Korean Patent Application No. 10-2023-0182086, filed on Dec. 14, 2023, in the Korean Intellectual Property Office, the disclosure of which is incorporated by reference herein in its entirety.

### BACKGROUND

### 1. Field

Embodiments relate to a display device and a method of manufacturing a display device.

### 2. Description of the Related Art

Mobile electronic devices have become widely used. In addition to small electronic devices such as mobile phones, tablet personal computers (PCs) have recently become widely used as mobile electronic devices.

In order to support various functions, such mobile electronic devices include a display device for providing a user with visual information, such as images or video. Recently, as other parts for driving the display device have become smaller, the proportion occupied by display devices in electronic devices has been gradually increasing, and a structure capable of being bent from a flat state to have an angle has also been developed.

### SUMMARY

Embodiments may provide improved adhesion between a capping layer and a first inorganic encapsulation layer.

In addition, embodiments may provide include improved adhesion between an organic encapsulation layer and a second inorganic encapsulation layer.

However, these aspects are examples, and the embodiments are not limited thereto.

Additional aspects will be set forth in part in the description which follows and, in part, will be apparent from the description, or may be learned by practice of the presented embodiments of the disclosure.

According to an embodiment, a display device includes a substrate, a pixel circuit layer disposed on the substrate and including a thin-film transistor, a display element layer disposed on the pixel circuit layer and including a pixel electrode, a capping layer disposed on the display element layer and including an organic material, and an encapsulation layer disposed on the capping layer, wherein the encapsulation layer includes a first inorganic encapsulation layer, an organic encapsulation layer disposed on the first inorganic encapsulation layer, and a second inorganic encapsulation layer disposed on the organic encapsulation layer, wherein the capping layer includes a first capping layer portion, and a second capping layer portion disposed on the first capping layer portion and in contact with the first inorganic encapsulation layer, the second capping layer portion having a higher concentration of hydrogen than the first capping layer portion.

In the present embodiment, the second capping layer portion may include an oxygen material combined with hydrogen.

In the present embodiment, the second capping layer portion may be more hydrophobic than the first capping layer portion.

In the present embodiment, an upper surface of the second capping layer portion may include an uneven shape.

In the present embodiment, the organic encapsulation layer may include a first organic encapsulation layer portion, and a second organic encapsulation layer portion disposed on the first organic encapsulation layer portion and in contact with the second inorganic encapsulation layer, the second organic encapsulation layer portion having a higher concentration of hydrogen than the first organic encapsulation layer portion.

In the present embodiment, the second organic encapsulation layer portion may include an oxygen material combined with hydrogen.

In the present embodiment, the second organic encapsulation layer portion may be more hydrophobic than the first organic encapsulation layer portion.

In the present embodiment, an upper surface of the second organic encapsulation layer portion may include an uneven shape.

According to an embodiment, a method of manufacturing a display device includes placing a substrate on a susceptor inside a chamber, forming a pixel circuit layer on the substrate, forming a display element layer on the pixel circuit layer, forming a capping layer on the display element layer, performing a hydrogen plasma treatment on the capping layer, forming a first inorganic encapsulation layer on the capping layer, forming an organic encapsulation layer on the first inorganic encapsulation layer, and forming a second inorganic encapsulation layer on the organic encapsulation layer, wherein the capping layer includes a first capping layer portion, and a second capping layer portion formed on the first capping layer portion and in contact with the first inorganic encapsulation layer, the second capping layer portion having a higher concentration of hydrogen than the first capping layer portion.

In the present embodiment, in the performing of the hydrogen plasma treatment on the capping layer, a time for which the capping layer is exposed to hydrogen may be set to be from about 10 seconds to about 60 seconds.

In the present embodiment, in the performing of the hydrogen plasma treatment on the capping layer, a distance between the susceptor and a head portion configured to eject hydrogen may be set to be from about 1000 mils to about 1500 mils.

In the present embodiment, in the performing of the hydrogen plasma treatment on the capping layer, an internal pressure of the chamber may be set to be from about 1000 mtorr to about 1500 mtorr.

In the present embodiment, in the performing of the hydrogen plasma treatment on the capping layer, a flow rate of hydrogen ejected from a head portion may be set to be from about 20000 sccm to about 40000 sccm.

In the present embodiment, the second capping layer portion may include an oxygen material combined with hydrogen.

In the present embodiment, the second capping layer portion may be more hydrophobic than the first capping layer portion.

In the present embodiment, an upper surface of the second capping layer portion may include an uneven shape.

In the present embodiment, the method may further include performing a hydrogen plasma treatment on the organic encapsulation layer, wherein the organic encapsulation layer may include a first organic encapsulation layer portion, and a second organic encapsulation layer portion formed on the first organic encapsulation layer portion and in contact with the second inorganic encapsulation layer, the second organic encapsulation layer portion having a higher concentration of hydrogen than the first organic encapsulation layer portion.

In the present embodiment, the second organic encapsulation layer portion may include an oxygen material combined with hydrogen.

In the present embodiment, the second organic encapsulation layer portion may be more hydrophobic than the first organic encapsulation layer portion.

In the present embodiment, an upper surface of the second organic encapsulation layer portion may include an uneven shape.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display device according to an embodiment;

FIG. 2 is a schematic cross-sectional view of a display device according to an embodiment;

FIG. 3 is an equivalent circuit diagram of any one pixel in a display device, according to an embodiment;

FIG. 4 is a schematic cross-sectional view of a display device according to an embodiment;

FIG. 5 is a schematic cross-sectional view of an apparatus for manufacturing a display device, according to an embodiment; and

FIG. 6 is a schematic flowchart of a method of manufacturing a display device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B. ” Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order.

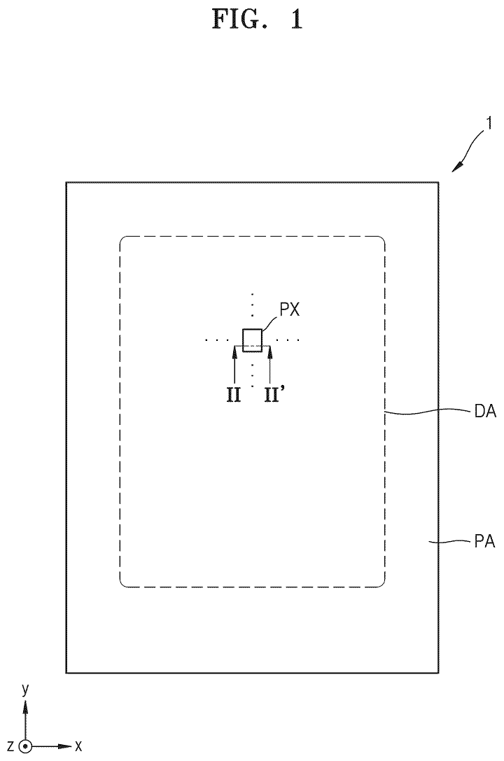

FIG. 1 is a schematic plan view of a display device 1 according to an embodiment.

Referring to FIG. 1, the display device 1 manufactured according to an embodiment may include a display area DA and a peripheral area PA located outside the display area DA. The display device 1 may provide an image through an array of a plurality of pixels PX two-dimensionally arranged in the display area DA.

The peripheral area PA is an area where no image is provided, and may entirely or partially surround the display area DA. A driver for providing an electrical signal or power to a pixel circuit corresponding to each of the pixels PX may be arranged in the peripheral area PA. A pad, which is an area to which an electronic element or a printed circuit board may be electrically connected, may be arranged in the peripheral area PA.

Hereinafter, it is assumed that the display device 1 includes an organic light-emitting diode (OLED) as a light-emitting element, but the display device 1 described herein is not limited thereto. In another embodiment, the display device 1 may be a light-emitting display device including an inorganic light-emitting diode, that is, an inorganic light-emitting display device. The inorganic light-emitting diode may include a PN junction diode including inorganic semiconductor-based materials. When a voltage is applied to the PN junction diode in a forward direction, holes and electrons are injected, and light of a certain color may be emitted by converting energy generated by recombination of the holes and electrons into light energy. The inorganic light-emitting diode described above may have a width of several to hundreds of micrometers, and in some embodiments, the inorganic light-emitting diode may be referred to as a micro LED. In another embodiment, the display device 1 may be a quantum dot light-emitting display device.

The display device 1 may be used as the display screen of not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various products, such as a television, a notebook computer, a monitor, a billboard, and an Internet of things (IoT) device. In addition, the display device 1 according to an embodiment may be used in wearable devices, such as a smartwatch, a watch phone, a glasses-type display, and a head-mounted display (HMD). In addition, the display device 1 according to an embodiment may be used as a car's instrument panel, a center information display (CID) placed on a car's center fascia or dashboard, a room mirror display replacing a car's side mirror, or a display screen placed on the back of a front seat as entertainment for a car's rear seat.

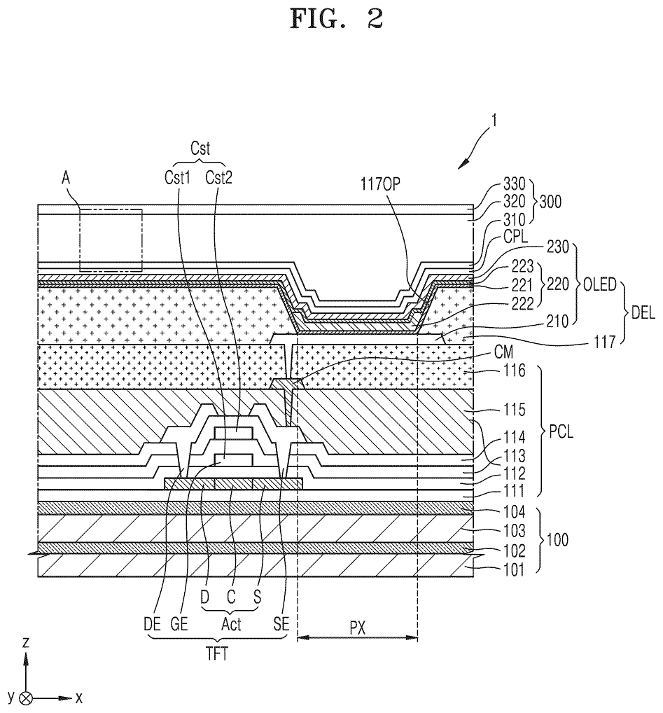

FIG. 2 is a schematic cross-sectional view of the display device 1 according to an embodiment, and may correspond to a cross-section of the display device 1, taken along a line II-II′ of FIG. 1.

Referring to FIG. 2, the display device 1 may include a stacked structure of a substrate 100, a pixel circuit layer PCL, a display element layer DEL, a capping layer CPL, and an encapsulation layer 300.

The substrate 100 may have a multi-layer structure including a base layer and an inorganic layer, the base layer including polymer resin. For example, the substrate 100 may include a base layer including polymer resin, and a barrier layer of an inorganic insulating layer. For example, the substrate 100 may include a first base layer 101, a first barrier layer 102, a second base layer 103, and a second barrier layer 104 which are sequentially stacked on one another. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC) or cellulose acetate propionate (CAP). The first barrier layer 102 and the second barrier layer 104 may include an inorganic insulating material, such as silicon oxide, silicon oxynitride or silicon nitride. The substrate 100 may be flexible.

The pixel circuit layer PCL is disposed on the substrate 100. FIG. 2 shows the pixel circuit layer PCL including a thin-film transistor TFT, and a buffer layer 111, a first gate insulating layer 112, a second gate insulating layer 113, an interlayer insulating layer 114, a first planarization insulating layer 115, and a second planarization insulating layer 116 disposed under or over elements of the thin-film transistor TFT.

The buffer layer 111 may reduce or prevent penetration of foreign materials, moisture, or external air from below the substrate 100 and may provide a flat surface on the substrate 100. The buffer layer 111 may include an inorganic insulating material, such as silicon oxide, silicon oxynitride or silicon nitride, and may have a single-layer or multi-layer structure including the above-described material.

The thin-film transistor TFT on the buffer layer 111 may include a semiconductor layer Act, and the semiconductor layer Act may include polysilicon (poly-Si). Alternatively, the semiconductor layer Act may include amorphous silicon (a-Si), an oxide semiconductor, or an organic semiconductor. The semiconductor layer Act may include a channel region C, and a drain region D and a source region S respectively arranged on both sides of the channel region C. A gate electrode GE may overlap the channel region C.

The gate electrode GE may include a low-resistance metal material. The gate electrode GE may include a conductive material including molybdenum (Mo), aluminum (Al), copper (Cu), titanium (Ti), etc., and may have a multi-layer or single-layer structure including the above-described material.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) or zinc peroxide (ZnO₂).

The second gate insulating layer 113 may cover the gate electrode GE. Similar to the first gate insulating layer 112, the second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) or zinc peroxide (ZnO₂).

An upper electrode Cst2 of a storage capacitor Cst may be disposed on the second gate insulating layer 113. The upper electrode Cst2 may overlap the gate electrode GE below. In this regard, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

As described above, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) or copper (Cu), and may have a single-layer or multi-layer structure including the above-described material.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) or zinc peroxide (ZnO₂). The interlayer insulating layer 114 may have a single-layer or multi-layer structure including the above-described inorganic insulating material.

Each of a drain electrode DE and a source electrode SE may be on the interlayer insulating layer 114. The drain electrode DE and the source electrode SE may be respectively connected to the drain region D and the source region S through contact holes defined in the insulating layers below. The drain electrode DE and the source electrode SE may include a highly conductive material. The drain electrode DE and the source electrode SE may include a conductive material including molybdenum (Mo), aluminum (Al), copper (Cu), titanium (Ti), etc., and may have a multi-layer or single-layer structure including the above-described material. In an embodiment, the drain electrode DE and the source electrode SE may have a multi-layer structure of titanium (Ti)/aluminum (Al)/titanium (Ti).

The first planarization insulating layer 115 may at least partially cover the drain electrode DE and the source electrode SE. The first planarization insulating layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second planarization insulating layer 116 may be disposed on the first planarization insulating layer 115. The second planarization insulating layer 116 may include the same material as that of the first planarization insulating layer 115, and may include an organic insulating material, such as a general commercial polymer, such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the pixel circuit layer PCL having the above-described structure. The display element layer DEL may include an organic light-emitting diode OLED as a display element (that is, a light-emitting element), and the organic light-emitting diode OLED may include a stacked structure of a pixel electrode 210, an intermediate layer 220, and a common electrode 230. The organic light-emitting diode OLED, for example, may emit red, green, or blue light, or may emit red, green, blue, or white light. The organic light-emitting diode OLED may emit light through an emission area, and the emission area may be defined as the pixel PX.

The pixel electrode 210 of the organic light-emitting diode OLED may be electrically connected to the thin-film transistor TFT through contact holes defined in the second planarization insulating layer 116 and the first planarization insulating layer 115 and a contact metal CM disposed on the first planarization insulating layer 115. That is, the pixel electrode 210 may be disposed over the substrate 100.

The pixel electrode 210 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a layer formed of ITO, IZO, ZnO, or In₂O₃ on/under the above-described reflection layer.

A bank layer 117 including an opening 117OP exposing a central portion of the pixel electrode 210 is disposed on the pixel electrode 210. The bank layer 117 may include an organic insulating material or an inorganic insulating material. The opening 117OP may define an emission area of light emitted from the organic light-emitting diode OLED. For example, a size/width of the opening 117OP may correspond to a size/width of the emission area. Accordingly, a size or width of the pixel PX may depend on a size or width of the corresponding opening 117OP of the bank layer 117.

The intermediate layer 220 may include an emission layer 222 corresponding to the pixel electrode 210. The emission layer 222 may include a polymer organic material or low-molecular weight organic material emitting light of a certain color. Alternatively, the emission layer 222 may include an inorganic light-emitting material or quantum dots. That is, the intermediate layer 220 may be disposed on the pixel electrode 210 to emit light.

In an embodiment, the intermediate layer 220 may include a first functional layer 221 and a second functional layer 223 respectively disposed under and on the emission layer 222. The first functional layer 221 may include, for example, a hole transport layer (HTL), or an HTL and a hole injection layer (HIL). The second functional layer 223 is an element disposed on the emission layer 222, and may include an electron transport layer (ETL) or an electron injection layer (EIL). Like the common electrode 230 described below, the first functional layer 221 or the second functional layer 223 may be a common layer entirely covering the substrate 100.

The common electrode 230 may be disposed over the pixel electrode 210 and may overlap the pixel electrode 210. The common electrode 230 may be disposed on the intermediate layer 220. The common electrode 230 may include a conductive material having a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 230 may further include a layer, such as ITO, IZO, ZnO, or In₂O₃, on a (semi)transparent layer including the above-described material. The common electrode 230 may be formed as a single body to entirely cover the substrate 100.

The capping layer CPL may be disposed on the display element layer DEL and may cover the display element layer DEL. That is, the capping layer CPL may be disposed on the common electrode 230. The capping layer CPL may have a high refractive index compared to the common electrode 230. According to one or more embodiments, the capping layer CPL with a relatively high refractive index is disposed on the common electrode 230, and reflectance of light emitted from the intermediate layer 220 at the common electrode 230 increases due to the capping layer CPL. Accordingly, resonance efficiency of microcavity improves, and thus, outcoupling efficiency of the organic light-emitting diode OLED increases.

In this regard, reflection at the common electrode 230 may be a concept including not only reflection at a lower surface of the common electrode 230 but also reflection at an interface between the common electrode 230 and the capping layer CPL and reflection at an interface between the capping layer CPL and the encapsulation layer 300.

The capping layer CPL may include an organic material. According to an embodiment, the capping layer CPL may include a triamine derivative, a carbazole biphenyl derivative, an arylenediamine derivative, or tris(8-hydroxyquinolinato)aluminum (Alq3).

The encapsulation layer 300 may be disposed on the capping layer CPL. That is, the encapsulation layer 300 may be disposed on the display element layer DEL and may cover the display element layer DEL. The encapsulation layer 300 may include at least one inorganic encapsulation layer and at least one organic encapsulation layer.

In the embodiment shown in FIG. 2, the encapsulation layer 300 includes a first inorganic encapsulation layer 310, an organic encapsulation layer 320, and a second inorganic encapsulation layer 330 sequentially stacked on one another. That is, the organic encapsulation layer 320 may be disposed on the first inorganic encapsulation layer 310, and the second inorganic encapsulation layer 330 may be disposed on the organic encapsulation layer 320.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate. The organic encapsulation layer 320 may be formed by curing a monomer or coating with a polymer. The organic encapsulation layer 320 may be transparent.

Although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may decrease reflectance of light (external light) incident from the outside toward a display device or may improve color purity of light emitted from the display device. In an embodiment, the optical functional layer may include a phase retarder or a polarizer. The phase retarder may be of a film type or a liquid crystal coating type and may include a λ/2 phase retarder or a λ/4 phase retarder. The polarizer may also be of a film type or a liquid crystal coating type. The film type may include an elongated synthetic resin film, and the liquid crystal coating type may include liquid crystals arranged in a certain arrangement. The phase retarder and the polarizer may further include a protection film.

An adhesive member may be disposed between the touch sensor layer and the optical functional layer. As the adhesive member, a general one known in the art may be employed without limitation. The adhesive member may be a pressure-sensitive adhesive (PSA).

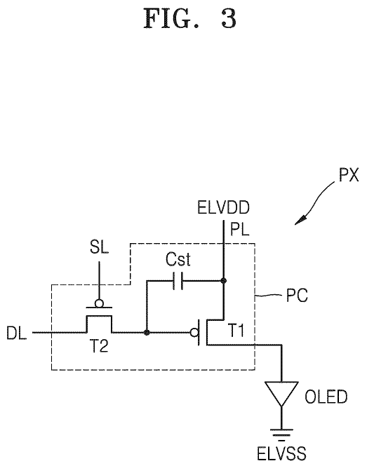

FIG. 3 is an equivalent circuit diagram of any one pixel in the display device 1, according to an embodiment.

Each pixel PX may include a pixel circuit PC and a display element connected to the pixel circuit PC, for example, the organic light-emitting diode OLED. The pixel circuit PC may include a first thin-film transistor T1, a second thin-film transistor T2, and the storage capacitor Cst. Each pixel PX may emit, for example, red, green, blue, or white light, through the organic light-emitting diode OLED.

The second thin-film transistor T2, which is a switching thin-film transistor, may be connected to a scan line SL and a data line DL, and may be configured to transfer a data voltage input from the data line DL to the first thin-film transistor T1, based on a switching voltage input from the scan line SL. The storage capacitor Cst may be connected to the second thin-film transistor T2 and a driving voltage line PL and may store a voltage corresponding to a difference between a voltage received from the second thin-film transistor T2 and a first power voltage ELVDD supplied to the driving voltage line PL.

The first thin-film transistor T1, which is a driving thin-film transistor, may be connected to the driving voltage line PL and the storage capacitor Cst, and may be configured to control a driving current flowing through the organic light-emitting diode OLED from the driving voltage line PL, in response to a voltage value stored in the storage capacitor Cst. The organic light-emitting diode OLED may emit light having certain brightness according to the driving current. A common electrode (e.g., a cathode) of the organic light-emitting diode OLED may receive a second power voltage ELVSS.

Although FIG. 3 shows the pixel circuit PC including two thin-film transistors and one storage capacitor, one or more embodiments are not limited thereto. The number of thin-film transistors and the number of storage capacitors may be variously modified according to the design of the pixel circuit PC. For example, the pixel circuit PC may further include four or five or more thin-film transistors in addition to the two thin-film transistors described above.

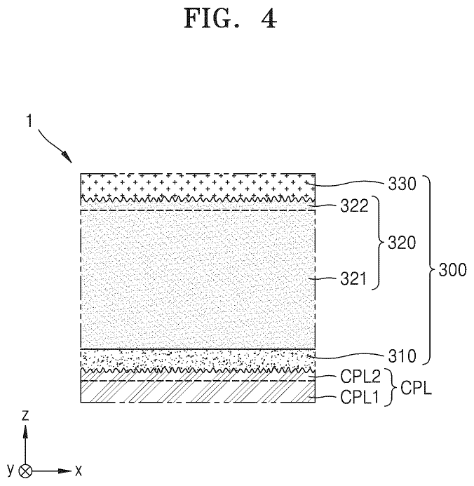

FIG. 4 is a schematic cross-sectional view of the display device 1 according to an embodiment and is an enlarged view of a region A of FIG. 2.

Referring to FIGS. 2 and 4, the capping layer CPL may include a first capping layer portion CPL1 and a second capping layer portion CPL2.

The second capping layer portion CPL2 may be disposed on the first capping layer portion CPL1. The first capping layer portion CPL1, the second capping layer portion CPL2, and the first inorganic encapsulation layer 310 may be sequentially stacked on one another in a direction away from the substrate 100 (e.g., +z-axis direction). The second capping layer portion CPL2 and the first inorganic encapsulation layer 310 may be in contact with each other. The first capping layer portion CPL1 and the second capping layer portion CPL2 may be integrally formed with each other.

As a hydrogen plasma treatment is performed on an upper portion of the capping layer CPL, the capping layer CPL may be divided into the first capping layer portion CPL1 and the second capping layer portion CPL2. That is, the second capping layer portion CPL2 disposed relatively above may have a higher concentration of hydrogen than the first capping layer portion CPL1.

Due to the hydrogen plasma treatment on the capping layer CPL, hydrogen gas may combine with oxygen of the capping layer CPL. Accordingly, the second capping layer portion CPL2 may include an oxygen material combined with hydrogen. In addition, oxygen of the second capping layer portion CPL2 may combine with hydrogen to form water and be discharged to the outside. Accordingly, the second capping layer portion CPL2 may be more hydrophobic than the first capping layer portion CPL1. Because hydrophobicity of the second capping layer portion CPL2 in contact with the first inorganic encapsulation layer 310 is strengthened, adhesion to an inorganic material may be improved. Thus, adhesion between the capping layer CPL and the first inorganic encapsulation layer 310 may be improved.

The capping layer CPL including an organic material may have a lower surface energy than the first inorganic encapsulation layer 310, which includes an inorganic material. Due to the hydrogen plasma treatment on the capping layer CPL, temperature of a surface of the capping layer CPL rises and the surface energy increases, and accordingly, a difference in surface energy between the capping layer CPL and the first inorganic encapsulation layer 310 may decrease. Thus, adhesion between the capping layer CPL and the first inorganic encapsulation layer 310 may be improved.

Because electrons collide with a surface of the second capping layer portion CPL2 during a process of performing the hydrogen plasma treatment on the capping layer CPL, part of the second capping layer portion CPL2 may be etched. Accordingly, the second capping layer portion CPL2 may include an uneven shape. That is, roughness of the surface of the second capping layer portion CPL2 may increase. Accordingly, a contact area between the second capping layer portion CPL2 and the first inorganic encapsulation layer 310 may increase. In addition, as part of the second capping layer portion CPL2 is etched, a foreign material on the surface of the second capping layer portion CPL2 may be removed. Thus, adhesion between the capping layer CPL and the first inorganic encapsulation layer 310 may be improved.

The organic encapsulation layer 320 may include a first organic encapsulation layer portion 321 and a second organic encapsulation layer portion 322. The second organic encapsulation layer portion 322 may be disposed on the first organic encapsulation layer portion 321. The first organic encapsulation layer portion 321, the second organic encapsulation layer portion 322, and the second inorganic encapsulation layer 330 may be sequentially stacked on one another in a direction away from the substrate 100 (e.g., +z-axis direction). The second organic encapsulation layer portion 322 and the second inorganic encapsulation layer 330 may be in contact with each other. The first organic encapsulation layer portion 321 and the second organic encapsulation layer portion 322 may be integrally formed with each other.

As a hydrogen plasma treatment is performed on an upper portion of the organic encapsulation layer 320, the organic encapsulation layer 320 may be divided into the first organic encapsulation layer portion 321 and the second organic encapsulation layer portion 322. That is, the second organic encapsulation layer portion 322 disposed relatively above may have a higher concentration of hydrogen than the first organic encapsulation layer portion 321.

Due to the hydrogen plasma treatment on the organic encapsulation layer 320, hydrogen gas may combine with oxygen of the organic encapsulation layer 320. Accordingly, the second organic encapsulation layer portion 322 may include an oxygen material combined with hydrogen. In addition, oxygen of the second organic encapsulation layer portion 322 may combine with hydrogen to form water and be discharged to the outside. Accordingly, the second organic encapsulation layer portion 322 may be more hydrophobic than the first organic encapsulation layer portion 321. Because hydrophobicity of the second organic encapsulation layer portion 322 in contact with the second inorganic encapsulation layer 330 is strengthened, adhesion to an inorganic material may be improved. Thus, adhesion between the organic encapsulation layer 320 and the second inorganic encapsulation layer 330 may be improved.

The organic encapsulation layer 320 including an organic material may have a lower surface energy than the second inorganic encapsulation layer 330, which includes an inorganic material. Due to the hydrogen plasma treatment on the organic encapsulation layer 320, temperature of a surface of the organic encapsulation layer 320 rises and the surface energy increases, and accordingly, a difference in surface energy between the organic encapsulation layer 320 and the second inorganic encapsulation layer 330 may decrease. Thus, adhesion between the organic encapsulation layer 320 and the second inorganic encapsulation layer 330 may be improved.

Because electrons collide with a surface of the second organic encapsulation layer portion 322 during a process of performing the hydrogen plasma treatment on the organic encapsulation layer 320, part of the second organic encapsulation layer portion 322 may be etched. Accordingly, the second organic encapsulation layer portion 322 may include an uneven shape. That is, roughness of the surface of the second organic encapsulation layer portion 322 may increase. Accordingly, a contact area between the second organic encapsulation layer portion 322 and the second inorganic encapsulation layer 330 may increase. In addition, as part of the second organic encapsulation layer portion 322 is etched, a foreign material on the surface of the second organic encapsulation layer portion 322 may be removed. Thus, adhesion between the organic encapsulation layer 320 and the second inorganic encapsulation layer 330 may be improved.

As adhesion between the capping layer CPL and the first inorganic encapsulation layer 310 is improved, and adhesion between the organic encapsulation layer 320 and the second inorganic encapsulation layer 330 is improved, durability of the display device 1 may be improved.

For example, during an operation of depositing the first inorganic encapsulation layer 310 on the capping layer CPL through a deposition mask, an error may occur in the alignment between the capping layer CPL and the first inorganic encapsulation layer 310 due to a shadow phenomenon. In the present embodiment, even when adhesion between two elements decreases because of an error in the alignment between the capping layer CPL and the first inorganic encapsulation layer 310, the reduction in adhesion may be offset.

For example, adhesion between the capping layer CPL and the first inorganic encapsulation layer 310 may decrease due to a difference in compressive stress between the capping layer CPL and the first inorganic encapsulation layer 310, and adhesion between the organic encapsulation layer 320 and the second inorganic encapsulation layer 330 may decrease due to a difference in compressive stress between the organic encapsulation layer 320 and the second inorganic encapsulation layer 330. In the present embodiment, even when adhesion decreases due to a difference in compressive stress between two elements, the reduction in adhesion may be offset.

As adhesion between the capping layer CPL and the first inorganic encapsulation layer 310 is improved, and adhesion between the organic encapsulation layer 320 and the second inorganic encapsulation layer 330 is improved, stability of manufacturing processes may be enhanced.

For example, during a process of manufacturing the display device 1, in an operation of removing a separate film from the display device 1, a phenomenon in which detachment occurs at an interface between the capping layer CPL and the first inorganic encapsulation layer 310 may be reduced. In addition, a phenomenon in which detachment occurs at an interface between the organic encapsulation layer 320 and the second inorganic encapsulation layer 330 may be reduced.

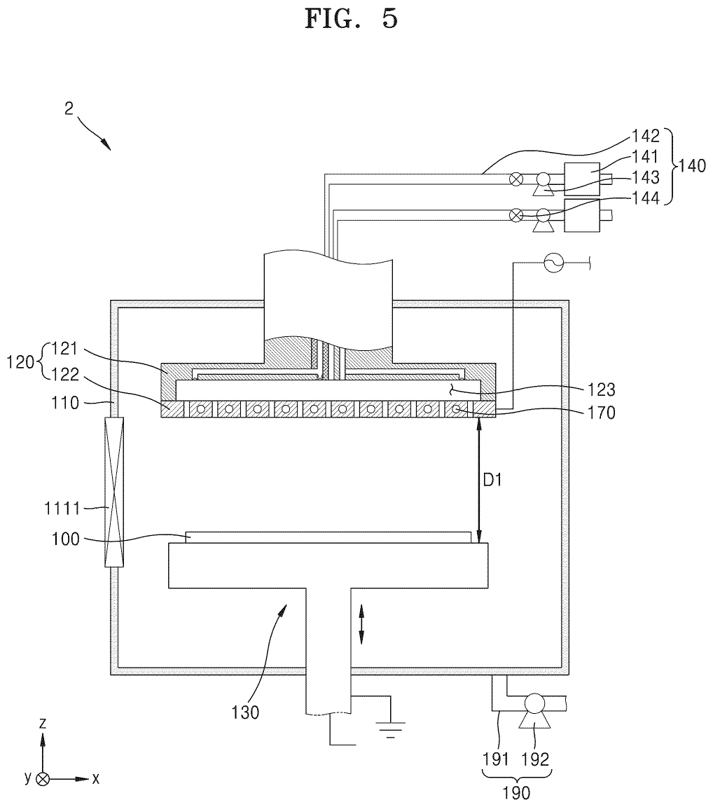

FIG. 5 is a schematic cross-sectional view of an apparatus 2 for manufacturing a display device, according to an embodiment.

Referring to FIG. 5, the apparatus 2 for manufacturing a display device may include a chamber 110, a head portion 120, a susceptor 130, a process gas supplier 140, an electrode portion 170, and a pressure controller 190.

The chamber 110 may have an internal space with an open portion, through which the substrate 100 may be transferred into or out of the chamber 110. In this regard, a gate valve 1111 may be arranged in an opening portion of the chamber 110 to open/close the opening portion of the chamber 110.

The head portion 120 may be arranged in the chamber 110 to supply a process gas to the inside of the chamber 110. In this regard, the head portion 120 may have a storage space 123 for storing the process gas. The head portion 120 may include a head body 121 connected to the process gas supplier 140. Further, the head portion 120 may include a nozzle 122 connecting the storage space 123 to the inside of the chamber 110 and configured to eject the process gas.

The susceptor 130 may face the head portion 120. In this regard, the substrate 100 may be placed on the susceptor 130 that is capable of moving up and down in the chamber 110. In addition, the susceptor 130 may adjust temperature of the substrate 100 or apply a certain voltage to the substrate 100. In another embodiment, the susceptor 130 may be connected to an external ground. In the following description, a case in which the susceptor 130 is connected to the external ground is mainly described for convenience.

The process gas supplier 140 may be arranged outside the chamber 110 and may be connected to the head portion 120. In this regard, the process gas supplier 140 may supply the process gas to the storage space 123 of the head portion 120. In this case, the process gas may be supplied to the head portion 120 to form one of an amorphous silicon (a-Si) film, a silicon nitride (SiNₓ) film, and a silicon oxide (SiOₓ) film. For example, the process gas may include any of a silane (SiH₄) gas, a hydrogen (H₂) gas, an ammonia (NH₃) gas, and a gas including a dopant element. Further, the process gas may include a carrier gas such as an argon (Ar) gas, a helium (He) gas, or a nitrogen (N₂) gas. In this regard, the selection of a process gas may influence the type of a film to be formed by the process gas. In the following description, a case in which the process gas includes silane and nitrogen gases is mainly described for convenience.

The process gas supplier 140 may include a plurality of process gas suppliers 140. In this case, as the plurality of process gas suppliers 140 individually store each process gas and are connected to the head portion 120, each process gas may be independently supplied to the head portion 120.

The process gas supplier 140 may include a process gas storing portion 141 for storing the process gas, and a process gas guide path 142 connecting the process gas storing portion 141 to the head portion 120 and configured to guide the process gas to flow from the process gas storing portion 141 to the storage space 123 of the head portion 120. Further, the process gas supplier 140 may include a process gas pump 143 arranged on the process gas guide path 142 to allow the process gas to flow, and a process gas shutoff valve 144 configured to stop or restart a flow of the process gas through the process gas guide path 142.

The electrode portion 170 may be arranged in the head portion 120. For example, the electrode portion 170 may include a plurality of electrode portions 170 in the nozzle 122. In another embodiment, the electrode portion 170 may be inserted in at least one of the nozzle 122 and the head body 121. In the following description, a case in which the electrode portions 170 are inserted in the nozzle 122 is mainly described for convenience.

The pressure controller 190 may be connected to the chamber 110 and may adjust the internal pressure of the chamber 110 by exhausting internal gas of the chamber 110 to the outside or supplying gas into the chamber 110. In this regard, the pressure controller 190 may include a guide pipe 191 connected to the chamber 110 and a pressure control pump 192 arranged along the guide pipe 191.

In the operation of the apparatus 2 for manufacturing a display device, after the pressure controller 190 adjusts the internal pressure of the chamber 110 to a level that is the same or similar to that of a certain pressure (e.g., atmospheric pressure or a pressure that is the same as the internal pressure of another chamber), the gate valve 1111 may operate to open the opening portion of the chamber 110. The substrate 100 may be inserted into the chamber 110 from the outside and placed on the susceptor 130. In this regard, the substrate 100 may enter the chamber 110 from the outside by means of, for example, a robot arm or a shuttle.

When the substrate 100 is pressed or placed onto the susceptor 130, the process gas supplier 140 may supply the process gas to the head portion 120. In this regard, a voltage may be applied to the electrode portion 170 to plasmarize the process gas, thereby depositing part of the process gas on the substrate 100. In this case, the apparatus 2 for manufacturing a display device may form one of various layers (or films) of the substrate 100. For example, the apparatus 2 for manufacturing a display device may form an amorphous silicon film on the substrate 100. In another embodiment, the apparatus 2 for manufacturing a display device may form an inorganic film of a thin-film encapsulation layer on the substrate 100. In the following description, a case in which the apparatus 2 for manufacturing a display device forms an inorganic film of a thin-film encapsulation layer on the substrate 100 is mainly described for convenience.

During a process of depositing part of a deposition gas on the substrate 100 as above, the pressure controller 190 may exhaust internal gas of the chamber 110 to the outside.

When the above process is completed, the pressure controller 190 may maintain the internal pressure of the chamber 110 in a certain pressure state, and the gate valve 1111 may operate to open the opening portion of the chamber 110. In addition, the robot arm or shuttle outside the chamber 110 may enter the chamber 110 to draw the substrate 100 where deposition has been completed to the outside of the chamber 110.

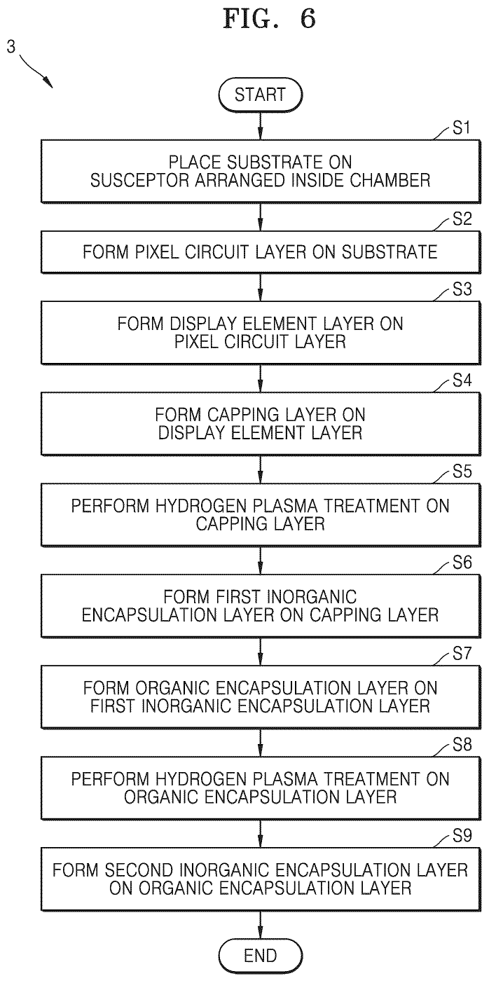

FIG. 6 is a schematic flowchart of a method 3 of manufacturing a display device, according to an embodiment.

In FIG. 6, the same reference numerals as those in FIGS. 1 to 5 denote the same elements, and thus, a repeated description thereof is omitted below.

Referring to FIGS. 2, 4, 5, and 6, the method 3 of manufacturing a display device may include an operation of placing the substrate 100 on the susceptor 130 inside the chamber 110 (in operation S1), an operation of forming the pixel circuit layer PCL on the substrate 100 (in operation S2), an operation of forming the display element layer DEL on the pixel circuit layer PCL (in operation S3), an operation of forming the capping layer CPL on the display element layer DEL (in operation S4), an operation of performing a hydrogen plasma treatment on the capping layer CPL (in operation S5), an operation of forming the first inorganic encapsulation layer 310 on the capping layer CPL (in operation S6), an operation of forming the organic encapsulation layer 320 on the first inorganic encapsulation layer 310 (in operation S7), an operation of performing a hydrogen plasma treatment on the organic encapsulation layer 320 (in operation S8), and an operation of forming the second inorganic encapsulation layer 330 on the organic encapsulation layer 320 (in operation S9).

Due to the operation of performing a hydrogen plasma treatment on the capping layer CPL (in operation S5), the capping layer CPL may be divided into the first capping layer portion CPL1 and the second capping layer portion CPL2.

For example, in the operation of performing a hydrogen plasma treatment on the capping layer CPL (in operation S5), the time for which the capping layer CPL is exposed to hydrogen may be set to be from about 10 seconds to about 60 seconds, a distance D1 between the susceptor 130 and the head portion 120 configured to eject hydrogen may be set to be from about 1000 mils to about 1500 mils, the internal pressure of the chamber 110 may be set to be from about 1000 mtorr to about 1500 mtorr, the flow rate of hydrogen ejected from the head portion 120 may be set to be from about 20000 sccm to about 40000 sccm, and the power applied to the electrode portion 170 may be set to at least 2500 W but not more than 7000 W.

Due to the operation of performing a hydrogen plasma treatment on the organic encapsulation layer 320 (in operation S8), the organic encapsulation layer 320 may be divided into the first organic encapsulation layer portion 321 and the second organic encapsulation layer portion 322.

The operation of performing a hydrogen plasma treatment on the organic encapsulation layer 320 (in operation S8) may be performed under the same process conditions as the operation of performing a hydrogen plasma treatment on the capping layer CPL (in operation S5).

For example, in the operation of performing a hydrogen plasma treatment on the organic encapsulation layer 320 (in operation S8), the time for which the organic encapsulation layer 320 is exposed to hydrogen may be set to be from about 10 seconds to about 60 seconds, the distance D1 between the susceptor 130 and the head portion 120 configured to eject hydrogen may be set to be from about 1000 mils to about 1500 mils, the internal pressure of the chamber 110 may be set to be from about 1000 mtorr to about 1500 mtorr, the flow rate of hydrogen ejected from the head portion 120 may be set to be from about 20000 sccm to about 40000 sccm, and the power applied to the electrode portion 170 may be set to at least 2500 W but not more than 7000 W.

According to one or more of the embodiments described above, stability of a process of manufacturing a display device may be improved, and durability of a display device may be improved.

Effects of one or more embodiments are not limited thereto, and other unmentioned effects will be apparent to one of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a pixel circuit layer disposed on the substrate and comprising a thin-film transistor;
a display element layer disposed on the pixel circuit layer and comprising a pixel electrode;
a capping layer disposed on the display element layer and comprising an organic material; and
an encapsulation layer disposed on the capping layer,
wherein the encapsulation layer comprises:
a first inorganic encapsulation layer;
an organic encapsulation layer disposed on the first inorganic encapsulation layer; and
a second inorganic encapsulation layer disposed on the organic encapsulation layer,
wherein the capping layer comprises:
a first capping layer portion; and
a second capping layer portion disposed on the first capping layer portion and in contact with the first inorganic encapsulation layer, the second capping layer portion having a higher concentration of hydrogen than the first capping layer portion.

2. The display device of claim 1, wherein the second capping layer portion comprises an oxygen material combined with hydrogen.

3. The display device of claim 1, wherein the second capping layer portion is more hydrophobic than the first capping layer portion.

4. The display device of claim 1, wherein an upper surface of the second capping layer portion comprises an uneven shape.

5. The display device of claim 1, wherein the organic encapsulation layer comprises:
a first organic encapsulation layer portion; and
a second organic encapsulation layer portion disposed on the first organic encapsulation layer portion and in contact with the second inorganic encapsulation layer, the second organic encapsulation layer portion having a higher concentration of hydrogen than the first organic encapsulation layer portion.

6. The display device of claim 5, wherein the second organic encapsulation layer portion comprises an oxygen material combined with hydrogen.

7. The display device of claim 5, wherein the second organic encapsulation layer portion is more hydrophobic than the first organic encapsulation layer portion.

8. The display device of claim 5, wherein an upper surface of the second organic encapsulation layer portion comprises an uneven shape.

9. A method of manufacturing a display device, the method comprising:
placing a substrate on a susceptor inside a chamber;
forming a pixel circuit layer on the substrate;
forming a display element layer on the pixel circuit layer;
forming a capping layer on the display element layer;
performing a hydrogen plasma treatment on the capping layer;
forming a first inorganic encapsulation layer on the capping layer;
forming an organic encapsulation layer on the first inorganic encapsulation layer; and
forming a second inorganic encapsulation layer on the organic encapsulation layer,
wherein the capping layer comprises:
a first capping layer portion; and
a second capping layer portion formed on the first capping layer portion and in contact with the first inorganic encapsulation layer, the second capping layer portion having a higher concentration of hydrogen than the first capping layer portion.

10. The method of claim 9, wherein, in the performing of the hydrogen plasma treatment on the capping layer, a time for which the capping layer is exposed to hydrogen is set to be from about 10 seconds to about 60 seconds.

11. The method of claim 9, wherein, in the performing of the hydrogen plasma treatment on the capping layer, a distance between the susceptor and a head portion configured to eject hydrogen is set to be from about 1000 mils to about 1500 mils.

12. The method of claim 9, wherein, in the performing of the hydrogen plasma treatment on the capping layer, an internal pressure of the chamber is set to be from about 1000 mtorr to about 1500 mtorr.

13. The method of claim 9, wherein, in the performing of the hydrogen plasma treatment on the capping layer, a flow rate of hydrogen ejected from a head portion is set to be from about 20000 sccm to about 40000 sccm.

14. The method of claim 9, wherein the second capping layer portion comprises an oxygen material combined with hydrogen.

15. The method of claim 9, wherein the second capping layer portion is more hydrophobic than the first capping layer portion.

16. The method of claim 9, wherein an upper surface of the second capping layer portion comprises an uneven shape.

17. The method of claim 9, further comprising performing a hydrogen plasma treatment on the organic encapsulation layer,
wherein the organic encapsulation layer comprises:
a first organic encapsulation layer portion; and
a second organic encapsulation layer portion formed on the first organic encapsulation layer portion and in contact with the second inorganic encapsulation layer, the second organic encapsulation layer portion having a higher concentration of hydrogen than the first organic encapsulation layer portion.

18. The method of claim 17, wherein the second organic encapsulation layer portion comprises an oxygen material combined with hydrogen.

19. The method of claim 17, wherein the second organic encapsulation layer portion is more hydrophobic than the first organic encapsulation layer portion.

20. The method of claim 17, wherein an upper surface of the second organic encapsulation layer portion comprises an uneven shape.
